(19) United States
(12) Patent Application Publication
(10) Pub. No.: US 2025/0321359 A1
(43) Pub. Date: Oct. 16, 2025

(54) TRANSPARENT OPTICAL ELEMENT FOR A VEHICLE

(71) Applicant: VALEO VISION, Bobigny Cedex (FR)

(72) Inventors: Marc BRASSIER, Bobigny Cedex (FR); Damien REVOL, Bobigny Cedex (FR); Leila OULHAZME, Bobigny Cedex (FR)

(73) Assignee: VALEO VISION, Bobigny Cedex (FR)

(21) Appl. No.: 18/576,943

(22) PCT Filed: Jul. 5, 2022
(86) PCT No.: PCT/EP2022/068651

§ 371 Date: Jan. 23, 2025

(30) Foreign Application Priority Data
Jul. 8, 2021 (FR) FR2107427

(51) Int. Cl. G02B 1/10; C23C 16/503; C23C 16/515

(52) U.S. Cl. CPC G02B 1/10; C23C 16/503; C23C 16/515

(57) ABSTRACT

A transparent optical element for a vehicle, in particular a motor vehicle, includes at least one first transparent layer made of a polymer material. The transparent optical element includes at least one transparent second layer formed by the polymerization of at least one precursor compound, the polymerization being assisted by atmospheric plasma with volume dielectric barrier discharge.

The present invention relates to the field of functional coatings for optical modules of motor vehicles. More precisely, the invention relates to an optical element for a vehicle, notably a motor vehicle, comprising a substrate on which a layer is deposited by means of a volume dielectric barrier atmospheric discharge plasma.

Electromagnetic emission devices for motor vehicles, such as headlamps, taillights and interior lighting systems or remote sensing devices, typically comprise a housing, in which an electromagnetic source is housed, and an optical element for closing the housing. This optical element may be an outer lens that is transparent to the electromagnetic waves emitted by the electromagnetic source. The optical element generally has several properties which meet customer requirements. These properties are notably due to at least one layer of a coating deposited on a substrate. Thus, the optical element may have, for example, antifogging properties, antiabrasion properties, anti-reflective properties and/or self-healing properties.

A first process using an arc plasma is particularly suitable for antifogging or anti-condensation coatings. It consists in creating an electric arc between two electrodes in the presence of at least one precursor compound and at least one inert gas. However, the arc plasma is highly energetic, which generally has the consequence of destroying the organic part of the injected precursor compound(s). The deposited coatings are thus based on oxides, nitrides or oxynitrides, depending on the type of gas used.

A second process via plasma-assisted chemical vapor deposition is used for coatings requiring polymerization of an organic monomer. As this type of plasma is low in energy, it allows organic polymer-based coating layers to be produced from one or more organic monomers. However, with this process it is difficult to control the degree of polymerization and the degree of crosslinking of the polymers obtained.

In the present context, it is understood that the described deposition processes cannot be combined to deposit different layers of a coating. It is also very difficult to control the polymerization reactions and the degree of crosslinking of the polymers obtained. In addition, the layer(s) deposited via these processes have high thicknesses, in the micrometer range, which need to be reduced. Finally, these deposition processes make it difficult or even impossible to mix precursor compounds, thus preventing the deposition of a layer having all the abovementioned properties, and also other additional properties.

The object of the present invention is to overcome at least one of the abovementioned drawbacks and also to lead to other advantages by proposing a novel type of transparent optical element for motor vehicles.

The present invention proposes a transparent optical element for a vehicle, notably a motor vehicle, comprising at least a first transparent layer made of a polymer material, characterized in that the transparent optical element comprises at least a second transparent layer formed by polymerization of at least one precursor compound, the polymerization being assisted by means of a volume dielectric barrier atmospheric discharge plasma.

According to one embodiment, the volume dielectric barrier discharge is a silent discharge or a homogeneous glow discharge.

The term “transparent element” or “transparent layer” should be understood throughout the text hereinbelow to mean an element or layer which transmits at least one electromagnetic radiation, for example visible light or a radar wave, by refraction and through which objects can be seen with varying degrees of sharpness, for example, by an electromagnetic radiation detector with very little or even no dispersion. Preferably, the transmission of electromagnetic radiation through the transparent optical element is at least 87%. The transmission of electromagnetic radiation is the amount of electromagnetic radiation that the transparent optical element or transparent layer lets through from an incident electromagnetic radiation.

The transparent optical element of the invention may be of the motor vehicle glazing type, and may form part, for example, of a lighting device such as a headlamp, a taillight or even an interior lighting system. Thus, the transparent optical element may be a closing outer lens for a motor vehicle lighting device housing.

The transparent optical element of the invention may be of the bodywork element type, and may form part of a remote sensing system, for example. The detection system may be a radar device or a lidar device. The radar device is configured to emit radar waves. The lidar device is configured to emit light from the visible, infrared or ultraviolet spectrum, the light being produced by a laser.

The remote sensing system is thus generally integrated into a bodywork element, and the transparent optical element has an external appearance similar to that of the bodywork elements surrounding it. The transparent optical element may thus be opaque to visible light radiation and transparent to the electromagnetic radiation emitted by the remote sensing system, for instance radar waves or infrared or else ultraviolet radiation.

A volume dielectric barrier atmospheric discharge plasma, also known as a dielectric barrier diffusion atmospheric plasma, is a type of plasma whose energy lies between the energy of a plasma-assisted chemical vapor deposition and the energy of an arc plasma. Thus, a volume dielectric barrier atmospheric discharge plasma allows one or more organic monomers to be polymerized, affording an organic polymer with a desired degree of polymerization. In addition, a volume dielectric barrier atmospheric discharge plasma e allows the polymer to be crosslinked in the presence or absence of at least one crosslinking agent to obtain a desired degree of crosslinking. Consequently, it is easy to control the properties of the polymer thus obtained and thus the properties of the transparent optical element.

According to one embodiment, the second layer has a thickness of not more than 1 micrometer, preferentially not more than 100 nm, more preferentially not more than 30 nm.

According to one embodiment, the second layer is a hydrophilic layer.

According to one embodiment, the second layer is a hydrophobic layer.

According to one embodiment, the second layer is an anticorrosion layer.

According to one embodiment, the second layer is in direct physical contact with the first layer.

According to one embodiment, the precursor compound is in liquid form, and/or is dissolved in a solvent, and/or is diluted in solvent.

According to one embodiment, the volumetric flow rate of the precursor compound is between 0.5 ls/min and 1.5 ls/min, preferentially equal to 1 ls/min.

According to one embodiment, the precursor compound is chosen from an organic monomer, an organometallic monomer, an organic prepolymer and mixtures thereof.

According to one embodiment, the precursor compound is chosen from acrylic acid, polyvinyl alcohol, ethyl acetate, perfluorodecyltriethylsilane, fluoromethacrylate, bis(triethoxysilyl)ethane, hexamethyldisilazane (HMDSN), hexamethyldisiloxane (HMDSO), octamethylcyclotetrasiloxane (OMCTSO), polydimethylsiloxane (PDMS), tetraethyl orthosilicate (TEOS), titanium isopropoxide (TTIP), aminopropyltriethoxysilane (APTES), acetylene, methane, tetraglyme (tetraethylene glycol dimethyl ether), aminopropyltriethoxysilane, hydroxyethyl methacrylate and polyethylene glycol.

According to one embodiment, the polymerization of the precursor compound (PC1) is performed in the presence of a second precursor compound (PC2).

According to one embodiment, the second precursor compound (PC2) is a crosslinking agent.

According to one embodiment, the crosslinking agent is chosen from glutaraldehyde, ethylene glycol dimethacrylate and mixtures thereof.

According to one embodiment, the transparent optical element comprises a plurality of transparent second layers, each second layer being formed by polymerization of at least one precursor compound, the polymerization being assisted by means of a volume dielectric barrier atmospheric discharge plasma. Thus, the second layers are superimposed on each other, one of the second layers being in physical contact with the first layer. The precursor compound may be the same for each layer or different for each layer.

According to one embodiment, the plasma is created and maintained by an ionizable gas introduced between two electrodes separated by a dielectric, the electrodes being supplied with electric current by means of an electric generator configured to provide an electrical power of between 50 W and 500 W, preferentially between 80 W and 450 W.

According to one embodiment, the ionizable gas is non-polymerizable.

According to one embodiment, the ionizable gas is neutral.

According to one embodiment, the ionizable gas is chosen from nitrogen, air, helium, argon and mixtures thereof. The ionizable gas is preferentially chosen from nitrogen, argon and a mixture thereof.

According to one embodiment, the volumetric flow rate of the ionizable gas is between 60 ls/min and 100 ls/min, preferentially between 70 ls/min and 90 ls/min; more preferentially, the volumetric flow rate of the ionizable gas is substantially equal to 80 ls/min.

The unit ls/min means “standard liter per minute”, the standard conditions corresponding to a pressure of 1013 mbar and a temperature of 20° C. If need be, preference will be given to the unit L/min, measured under said standard conditions.

According to one embodiment, a dilution gas is used to adjust the concentration of the precursor compound injected into the volume dielectric barrier atmospheric discharge plasma.

According to one embodiment, the dilution gas is chosen from carbon dioxide, oxygen, nitrogen, argon and mixtures thereof.

According to one embodiment, the volumetric flow rate of the dilution gas is between 2 ls/min and 8 ls/min, preferably between 4 ls/min and 6 ls/min; more preferentially, the volumetric flow rate of the dilution gas is substantially equal to 5 ls/min.

According to one embodiment, the ionizable gas and the dilution gas are identical.

According to one embodiment, the polymer material of the first transparent layer comprises at least one polymer P chosen from polycarbonate (PC), high-temperature-modified polycarbonate (PC-HT), polymethyl methacrylate (PMMA), polymethacryl methyl imide (PMMI), cycloolefin polymer (COP), cycloolefin copolymer (COC), polysulfone (PSU), polyarylate (PAR), polyamide (PA), and mixtures thereof.

According to one embodiment, the polymer material may comprise only one or more polymers P.

According to one embodiment, the polymer material is activated by means of an activating gas.

According to one embodiment, the activating gas is chosen from argon, oxygen, sulfur hexafluoride and a mixture thereof.

According to one embodiment, the polymer material is at least partly covered with a metal deposit chosen from aluminum, iron, nickel, copper, indium, chromium, zinc, tin and a mixture thereof. It is understood in this context that the polymer material forms a first sublayer of the first transparent layer and the metal deposit forms a second sublayer of the first transparent layer, the second sublayer being in direct contact with the first sublayer of the first transparent layer.

The invention also relates to an electromagnetic emission device for a vehicle, notably a motor vehicle, comprising at least one transparent optical element having at least one of the features described previously.

According to one embodiment, the electromagnetic emission device is a luminous device.

According to one embodiment, the luminous device is a headlamp, a taillight or an interior lighting system.

According to one embodiment, the electromagnetic emission device is a remote sensing system.

The invention also proposes a vehicle, notably a motor vehicle, comprising at least one electromagnetic emission device having at least one of the features described previously.

The invention also offers a process for depositing at least a second transparent layer on a first transparent layer, the process comprising a step of creating a volume dielectric barrier atmospheric discharge plasma, a step of injecting at least one precursor compound into the atmospheric plasma created so as to polymerize the precursor compound, and a step of depositing the product of polymerization of the precursor compound on the first layer, the deposit forming a second layer on the first layer.

According to one embodiment, the process comprises a step of activating the first layer prior to the injection step.

Other features and advantages of the invention will also emerge firstly from the following description, and secondly from several illustrative and nonlimiting examples given as a guide with reference to the appended schematic drawings, in which:

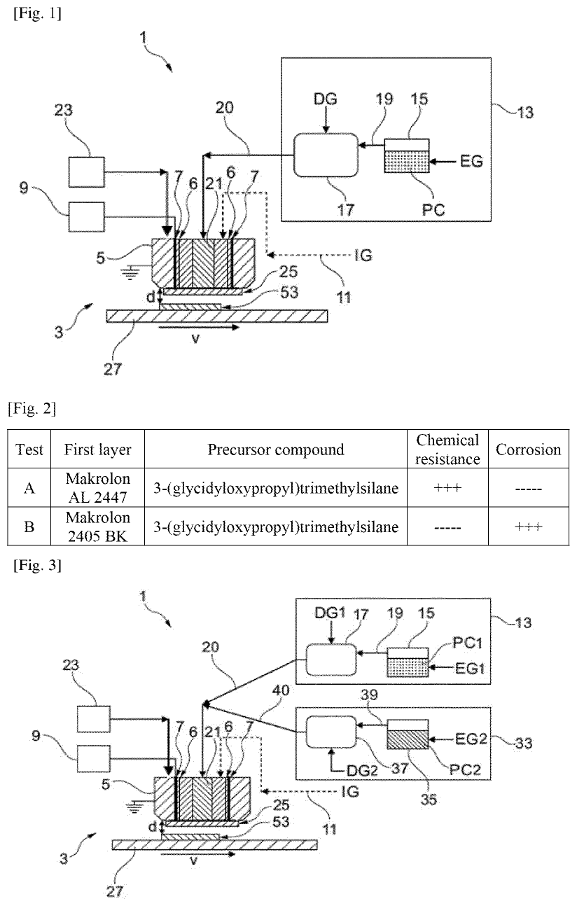

FIG. 1 schematically represents a first configuration of a device for depositing a second transparent layer of a transparent optical element according to the invention;

FIG. 2 is a table collating the results obtained by samples prepared according to a first embodiment using the first configuration of the deposition device shown in FIG. 2;

FIG. 3 schematically represents a second configuration of a device for depositing a second transparent layer of a transparent optical element according to the invention;

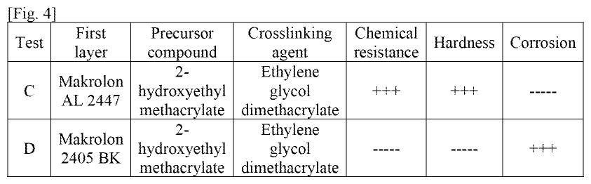

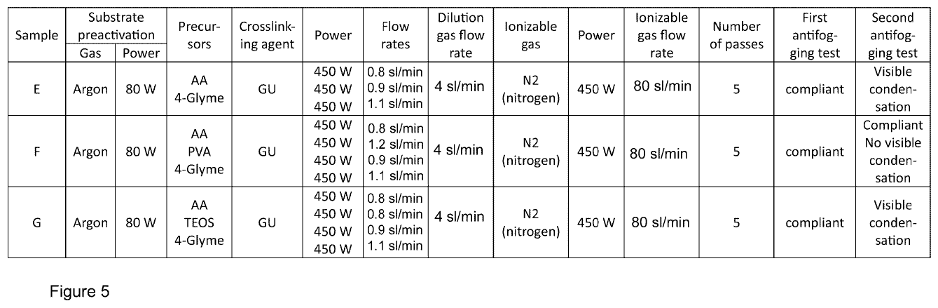

FIG. 4 is a table collating the results obtained by samples prepared according to a second embodiment using the second configuration of the deposition device shown in FIG. 3;

FIG. 5 is a table collating the results obtained by samples prepared according to a third embodiment;

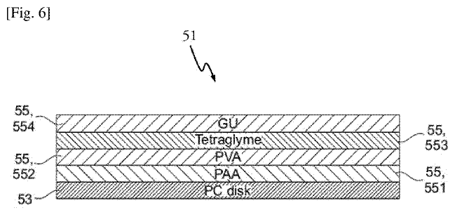

FIG. 6 is a schematic representation of the structure of a transparent optical element obtained according to the third embodiment.

The present invention relates to a transparent optical element which is noteworthy in that it comprises a second transparent layer deposited on a first transparent layer made of a polymer material, the second layer being obtained by polymerization of at least one precursor compound, the polymerization being assisted by means of a volume dielectric barrier atmospheric discharge plasma. The volume dielectric barrier discharge may be a silent discharge or a homogeneous glow discharge.

With reference to FIG. 1, a deposition device 1, for manufacturing and depositing at least one second transparent layer on at least one first transparent layer, comprises a plasma device 3 configured to generate a volume dielectric barrier atmospheric discharge plasma, more particularly an atmospheric silent-discharge plasma.

The plasma device 3 comprises an outer electrode 5 and an inner electrode 7 separated by means of at least one dielectric 6. The dielectric 6 is an electrically insulating element. The dielectric 6 is a ceramic, preferentially chosen from alumina (Al₂O₃), zirconium dioxide (ZrO₂) and a composite thereof.

The outer electrode 5 and the inner electrode 7 are concentric, the outer electrode 5 surrounding the inner electrode 7. The dielectric 6 is interposed between the two electrodes 5, 7.

In an embodiment not shown, the outer and inner electrodes extend in different planes parallel to each other. The electrodes of the plasma device are thus flat. The face of the outer electrode facing the inner electrode is covered with the dielectric. Optionally, the face of the inner electrode facing the outer electrode may also be covered with the dielectric.

The outer electrode 5 and the inner electrode 7 may be made of stainless steel. The distance between the outer electrode 5 and the inner electrode 7 may range from 1 millimeter to a few centimeters.

With reference to FIG. 1, the deposition device 1 comprises an electric generator 9 configured to raise the electrodes 5, 7 of the plasma device 3 to a high-frequency voltage. The high-frequency voltage is created by the electric generator 9 by bringing the inner electrode 7 to a high-frequency potential, the outer electrode 5 being connected to an earth of the electric generator 9.

The electric generator 9 may operate according to different modes chosen from direct current, pulsed direct current, microwave or radio frequency.

The electric generator 9 is configured to provide an electrical power of between 50 W and 500 W, preferentially between 80 W and 450 W.

When the electrodes 5, 7 of the plasma device 3 are brought to a high voltage, an unpolymerizable ionizable gas IG is introduced between the outer electrode 5 and the inner electrode 7 through a first pipe 11 so as to create the plasma. The plasma created is crown-shaped.

The high-frequency voltage is adjusted to comply with Paschen's law and thus allow plasma to be both initiated and maintained with the ionizable gas IG as a function of the inter-electrode distance, which is given by the geometry of the plasma device 3.

The unpolymerizable ionizable gas IG is generally neutral. It may be chosen from nitrogen, air, helium, argon and mixtures thereof. The ionizable gas flow rate is between 60 ls/min and 100 ls/min, preferentially between 70 ls/min and 90 ls/min; more preferentially, the ionizable gas flow rate is substantially equal to 80 ls/min.

The term “substantially” is understood here and throughout the text hereinbelow to mean that measurement tolerances, and also any calibration tolerances, must be taken into account.

The deposition device 1 comprises at least one spraying device 13 configured to form an aerosol of at least one precursor compound PC, which will then be injected into the plasma formed by the plasma device 3. The spraying device 13 comprises a storage container 15 for the precursor compound PC, connected to an atomizer 17 via a second pipe 19.

The atomizer 17 is configured to allow fine droplets of precursor compound PC to be sprayed from the storage container 15 via a spraying orifice. The spray of fine droplets forms an aerosol. The spray of fine droplets is fed into the plasma 25 via a channel delimited by an inner wall of the inner electrode 7, the channel 21 being connected to the spraying orifice of the atomizer 17 via a third pipe 20.

The precursor compound PC may be chosen from an organic monomer, an organometallic monomer, an organic prepolymer and mixtures thereof.

By way of example, the precursor compound PC may be chosen from acrylic acid, polyvinyl alcohol, ethyl acetate, perfluorodecyltriethylsilane, fluoromethacrylate, bis(triethoxysilyl)ethane, hexamethyldisilazane (HMDSN), hexamethyldisiloxane (HMDSO), octamethylcyclotetrasiloxane (OMCTSO), polydimethylsiloxane (PDMS), tetraethyl orthosilicate (TEOS), titanium isopropoxide (TIPP), aminopropyltriethoxysilane (APTES), acetylene, methane, tetraglyme (tetraethylene glycol dimethyl ether), aminopropyltriethoxysilane, hydroxyethyl methacrylate and polyethylene glycol.

It may be in liquid form, and/or dissolved in a solvent, and/or diluted in a solvent. The volumetric flow rate of the precursor compound PC in the second pipe 19 is between 0.5 ls/min and 1.5 ls/min, preferentially equal to 1 ls/min.

An entrainment gas EG is injected into the precursor compound PC storage container 13 so as to entrain the precursor compound toward the atomizer 17. The entrainment gas EG is an unpolymerizable inert gas. It is generally neutral. It may be chosen from nitrogen, air, helium, argon and mixtures thereof. Preferentially, the entrainment gas EG is identical to the ionizable gas IG. The volumetric flow rate of the entrainment gas EG in the storage container 15 is between 0.5 ls/min and 1.5 ls/min, preferentially substantially equal to 1 ls/min.

A dilution gas DG is injected into the atomizer 17 of the spraying device 13 at a given volumetric flow rate, so that it is mixed with the precursor compound PC and the entrainment gas EG within the atomizer 17. The dilution gas DG allows the amount of droplets in a given volume to be adjusted by adjusting a volumetric flow rate of the dilution gas DG feed. In other words, the concentration of precursor compound PC is adjusted within the atomizer 17. The dilution gas DG also allows the droplets to be propelled through the spraying orifice of the atomizer so as to send the aerosol into the plasma 25 via channel 21 of the inner electrode 7.

The dilution gas DG is chosen from carbon dioxide (CO₂), oxygen (O₂), nitrogen (N₂), argon and mixtures thereof. The dilution gas DG is injected into the atomizer 17 at a volumetric flow rate of between 2 ls/min and 8 ls/min, preferentially between 4 ls/min and 6 ls/min; more preferentially, the dilution gas volumetric flow rate is substantially equal to 5 ls/min.

The deposition device 1 comprises a compressed air feed 23. The compressed air feed 23 is used to cool the plasma device 3, in particular the inner electrode 7 and the outer electrode 5.

The deposition device 1 comprises a movable base 27, on which is arranged a support used as a first layer 53. Following injection of the precursor compound PC droplets into the plasma 25, the polymerization reaction occurs by virtue of the energy supplied by the plasma 25 obtained by silent discharge. The polymer obtained is then deposited on the first layer 53. The first layer 53 is moved at speed v via the base 27 to ensure uniform distribution of the second layer on the first layer 53. This may also allow the application of several second layers stacked one on top of the other. Between 5 and 20 passes are performed on the first layer 53 so as to deposit the second layer evenly.

The second layer(s) are each less than 1 micrometer thick. One side of the first layer 53 on which the second layer is deposited is at a distance d from a lower end of the plasma device 3. The distance d is measured along an axis perpendicular to the general plane of extension of the first layer 53.

### EXAMPLE

Two samples A, B are manufactured to obtain a transparent optical element with improved chemical resistance, corrosion protection and mechanical strength.

The supports used as the first layer are prepared from transparent polycarbonate (PC) sold by the company Covestro under the reference Makrolon AL 2447 and under the reference Makrolon 2405 BK. The support prepared from Makrolon 2405 BK features, on one side, a thin layer of aluminum deposited via a PVD (Physical Vapor Deposition) process, onto which the second layer is deposited by means of an atmospheric silent-discharge plasma.

The precursor compound PC is an organosilicon compound. More specifically, the precursor compound PC is (3-glycidyloxypropyl)trimethylsilane (CAS No. 2530-83-8) sold by the company Sigma-Aldrich under the reference 440167.

The nitrogen used as carrier gas, dilution gas and ionizable gas is sold by the company Air Liquide under the reference Alphagaz 1 Azote (CAS No. 7727-37-9).

The air used as a compressed gas is sold by the company Air Liquide under the reference Alphagaz 2 Air.

The atmospheric silent-discharge plasma deposition process is used to deposit the second layer on the first layer 53. The electric generator has a power rating of 450 W and generates pulsed DC current at 40 kHz. The pressure of the compressed air is 5 bar. The volumetric flow rate of the ionizable gas is 80 ls/min. The volumetric flow rate of the precursor compound is 1 ls/min. The volumetric flow rate of the dilution gas is 5 ls/min. The distance between a lower end of the plasma device 3 and the first layer is 4 mm. The speed v of the base 27 is 20 mm/sec. 15 passes are performed on the first layer 53.

Various tests were conducted on the parts thus treated: a chemical resistance test and a corrosion test. The results are collated in the table in FIG. 2.

For the chemical resistance test, the samples are immersed in an aqueous triethanolamine solution at 65° C. for 24 hours. The samples are rinsed with demineralized water. The samples are then inspected visually for the presence of cracks and/or crazing and/or at least one frosted portion of the surface.

For the corrosion test, the samples are placed for 48 hours at 40° C. in an atmosphere with a relative humidity of 100%. The samples are then inspected visually to observe one or more corrosion spots.

In FIG. 2, ---- indicates that the test was not performed; +++ indicates that there are no visible changes to the sample as a result of the chemical resistance test, or that there are no corrosion spots observed as a result of the corrosion test.

In a second embodiment illustrated in FIG. 2, the plasma device 3 may comprise a second spraying device 33 in addition to the spraying device described previously and which will be referred to hereinbelow as the first spraying device 13. The precursor compound PC will be referred to as the first precursor compound PC1. Consequently, for the elements that are identical between the first embodiment and the second embodiment, which are denoted by the same references, reference will be made to the description of FIG. 1 described above.

In the embodiment shown in FIG. 2, the second spraying device 33 is structurally identical to the first spraying device 13. However, they may be different without departing from the context of the present invention.

The second spraying device 33 is configured to form an aerosol of at least one second precursor compound PC2, which will then be injected into the silent-discharge plasma formed by the plasma device 3. The second precursor compound PC2 is different from the first precursor compound PC1.

This configuration makes it possible to form a copolymer for the second layer from the first precursor PC1 and the second precursor PC2. The second precursor PC2 may be chosen from an organic monomer, an organometallic monomer, a prepolymer and mixtures thereof. It may be in liquid form, and/or dissolved in a solvent, and/or diluted in a solvent. Preferentially, the aerosol comprising the first precursor compound PC1 and the aerosol comprising the second precursor compound PC2 are mixed before being injected into the silent-discharge plasma, as illustrated in FIG. 2.

Alternatively, it is possible to use a crosslinking agent as the precursor compound PC2 in addition to a monomer used as the precursor compound PC1 so as to control the degree of crosslinking of the polymer forming the second layer. The crosslinking agent may be chosen from glutaraldehyde, ethylene glycol dimethyl methacrylate and mixtures thereof. Preferentially, the aerosol comprising the first precursor compound PC1 and the aerosol comprising the second precursor compound PC2 are mixed before being injected into the plasma, as illustrated in FIG. 2.

It is also possible to use a first precursor compound PC1 and a second precursor compound PC2 which are immiscible and/or chemically mutually incompatible. For example, the first precursor compound PC1 and the second precursor compound PC2 may be chosen from acrylic acid, ethyl acetate, trimethylolpropane trimethacrylate, tetraglyme (tetraethylene glycol dimethyl ether), glutaramide, 1H,1H,2H,2H-perflurodecyltriethoxysilane, 3-aminopropyltriethoxysilane, 1H,1H,2H,2H-perfluorooctyltriethoxysilane, pentafluorophenylethoxydimethylsilane, and mixtures thereof. The first precursor compound is different from the second precursor compound. Preferentially, the aerosol comprising the first precursor compound PC1 and the aerosol comprising the second precursor compound PC2 are injected alternately before being injected into the plasma as illustrated in FIG. 2.

In addition, this configuration makes it possible to deposit a plurality of second layers of different types and with different properties. For example, it is possible to alternate hydrophilic second layers with hydrophobic second layers. Preferentially, the aerosol comprising the first precursor compound PC1 and the aerosol comprising the second precursor compound PC2 are injected alternately into the silent-discharge plasma.

As shown in FIG. 2, the second spraying device 33 comprises a storage container 35 for the second precursor compound PC2, connected to a second atomizer 37 via a fourth pipe 39. The second atomizer 37 allows fine droplets of the second precursor compound PC2 to be sprayed from the storage container 35 via a spraying orifice which is connected to the third pipe 20 via a fifth pipe 40. The spray of fine droplets of the second precursor compound PC2 forms an aerosol. The spray of fine droplets of second precursor compound PC2 is then mixed with the spray of fine droplets of first precursor compound PC1 at a junction between the third pipe 20 and the fifth pipe 40. The mixture thus obtained is then guided by the third pipe 20 to the plasma 25 via channel 21 of the inner electrode 7 plasma, which allows the mixture to be injected into the plasma 25 obtained by silent discharge.

An entrainment gas EG2 is injected into the second storage container 35 for the second precursor compound PC2 so as to entrain the second precursor compound PC2 toward the second atomizer 37. The entrainment gas EG injected into the second storage container 35 is an unpolymerizable inert gas. It is generally neutral. It may be chosen from nitrogen, air, helium, argon and mixtures thereof.

Preferentially, the entrainment gas EG2 injected into the second storage container 35 is identical to the entrainment gas EG injected into the first storage container 15. The entrainment gas EG2 injected into the second storage container 35 is preferentially identical to the ionizable gas IG. The volumetric flow rate of the entrainment gas EG2 in the second storage container 35 is between 0.5 ls/min and 1.5 ls/min, preferentially substantially equal to 1 ls/min.

A dilution gas DG2 is injected into the second atomizer 37 of the second spraying device 33 at a given volumetric flow rate so that it is mixed, in the second atomizer 37, with the second precursor compound PC2 and the entrainment gas EG2 injected into the second storage container 35. The dilution gas DG2 fed to the second spraying device 33 allows the droplet amount in a given volume to be adjusted by adjusting a volumetric flow rate of the dilution gas DG2 feed to the second spraying device 33. In other words, the concentration of second precursor compound PC2 is adjusted within the second atomizer 37. The dilution gas DG2 from the second spraying device 33 also allows the droplets to be propelled through the spraying orifice of the second atomizer 37 so as to send the aerosol into the plasma 25 via channel 21 of the inner electrode 7. The dilution gas DG2 is injected into the second atomizer 37 at a volumetric flow rate of between 2 ls/min and 8 ls/min, preferentially between 4 ls/min and 6 ls/min; more preferentially, the volumetric flow rate of the dilution gas is substantially equal to 5 ls/min.

### EXAMPLE

Two samples C, D are manufactured for the purpose of obtaining an optical element with improved chemical resistance, corrosion protection and mechanical strength.

The supports used as the first layer are prepared from transparent polycarbonate (PC) sold by the company Covestro under the reference Makrolon AL 2447 and under the reference Makrolon 2405 BK. The support prepared from Makrolon 2405 BK has, on one side, a thin layer of aluminum deposited via a PVD (Physical Vapor Deposition) process, onto which the second layer is deposited.

The first precursor compound PC1 is 2-hydroxyethyl methacrylate (CAS No. 7646-67-5) sold by the company Sigma-Aldrich under the reference 697931.

The second precursor compound PC2 is a crosslinking agent. More specifically, the second precursor compound PC2 is ethylene glycol dimethacrylate (CAS No. 97-90-5) sold by the company Sigma-Aldrich under the reference 335681.

The nitrogen used as entrainment gas in the first spraying device 13 and in the second spraying device 33, as dilution gas in the first spraying device 13 and in the second spraying device 33, and as ionizable gas is sold by the company Air Liquide under the reference Alphagaz 1 Azote (CAS No. 7727-37-9).

The air used as a compressed gas is sold by the company Air Liquide under the reference Alphagaz 2 Air.

The atmospheric silent-discharge plasma deposition process is used to deposit the second layer on the first layer 53. The power rating of the electric generator is 450 W. The pressure of the compressed air is 5 bar. The volumetric flow rate of the ionizable gas is 80 ls/min. The volumetric flow rate of the first precursor compound is 1 ls/min. The volumetric flow rate of the second precursor compound is 0.8 ls/min. The volumetric flow rate of the dilution gas is 5 ls/min. The distance d between a lower end of the plasma device 3 and the first layer 53 is 4 mm. The speed v of the base 27 is 20 mm/sec. 15 passes are performed to deposit the second layer.

A chemical resistance test or a corrosion test is performed on the samples. When the chemical resistance test is performed, a hardness test is also performed. The chemical resistance test and the corrosion test have been described previously.

For the hardness test, the samples undergo the hardness test according to the standard ISO 15184:2020. Briefly, the tip of a carbon graphite pencil with a hardness of between 9H and 9B on the HB scale is passed over one surface of the samples at a pressure of 2N. The tip is inclined at 45° relative to the normal to the plane in which the sample extends. The samples are then inspected visually for scratches. The results are collated in the table in FIG. 4.

In FIG. 4, ---- indicates that the test was not performed; +++ indicates that there are no visible changes to the sample as a result of the chemical resistance test, or that there are no scratches as a result of the hardness test, or that there are no corrosion spots observed as a result of the corrosion test.

In tests B and D, the second layer enabled the aluminum undercoat of the first layer to be protected against corrosion. It is understood that the second layer can protect layers based on readily oxidizable metals such as aluminum, iron, nickel or indium.

In a third embodiment, the deposition device comprises five spraying devices, each containing a different precursor compound. The precursors are injected in turn into the atmospheric silent-discharge plasma to form a stack of second layers, each second layer resulting from the polymerization of one of the precursor compounds injected into the silent-discharge plasma. In other words, the precursor compounds are never mixed together in this third embodiment.

The first layer is, optionally here, activated by means of a surface treatment with an activating gas before the second layers are deposited.

### EXAMPLE

Three samples E, F, G are manufactured to obtain a transparent optical element with improved antifogging properties.

The supports used as the first layer are each prepared from a transparent polycarbonate (PC) resin sold by the company Sabic under the reference LEXAN LS1-111 H.

The first layer is activated with argon gas. The dilution gas is nitrogen. The ionizable gas is nitrogen.

The first precursor compound PC1 is, in this third embodiment, acrylic acid (CAS No. 79-10-7) sold by the company Sigma-Aldrich under the reference number 147230.

The second precursor compound PC2 is polyvinyl alcohol (CAS No. 9002-89-5) sold by the company Sigma-Aldrich under the reference 341584. For use in the deposition device, an aqueous solution comprising 5% by weight of polyvinyl alcohol is prepared.

The third precursor compound PC3 is tetraethylene glycol dimethyl ether (4GLYME) (CAS No. 111-30-8) sold by the company Sigma-Aldrich under the reference number 147230.

The fourth precursor compound PC4 is glutaraldehyde (GU) (CAS No. 111-30-8) sold by the company Sigma-Aldrich under the number 340855. For its use in the deposition device, it is an aqueous solution comprising 50% by weight glutaraldehyde.

The fifth precursor compound PC5 is tetraethyl orthosilicate (TEOS) (CAS 78-10-4) sold by the company Sigma-Aldrich under the reference 131903.

The parameters used for the deposition device are summarized in Table 3.

Two antifogging tests were then performed on each sample. The first condensation test consisted in placing the samples 20 cm above a water bath at a temperature of 70° C.±10° C. for 5 sec. The samples are inspected visually for traces of condensation.

The second condensation test consists in placing the samples for 15 hours at 40° C. in an atmosphere with a relative humidity of 100%. The samples are then placed under ambient conditions and sprayed for 30 sec with water at 10° C.±2° C. The samples are then inspected visually for traces of condensation.

The results are collated in the table in FIG. 5.

FIG. 6 illustrates the structure of the transparent optical element 51 obtained in test F, which is considered to have the best antifogging test results. A plurality of second transparent layers 55 were deposited on the first transparent layer 51. A first second layer 55, 551 was deposited directly on the first layer 51. The first second layer 55, 551 results from the polymerization, with an atmospheric silent-discharge plasma, of the precursor compound PC1.

A second second layer 55, 552 was deposited directly on the first second layer 55, 551. The second second layer 55, 552 results from the polymerization of the second precursor compound PC2 by means of an atmospheric silent-discharge plasma.

A third second layer 55, 553 was deposited directly on the second second layer 55, 552. The third second layer 55, 553 results from the polymerization of the third precursor compound PC3 by means of an atmospheric silent-discharge plasma.

A fourth second layer 55, 554 was deposited directly on the third second layer 55, 553. The fourth second layer 55, 554 results from the polymerization, by means of an atmospheric silent-discharge plasma, of the fourth precursor compound PC4.

The embodiments and examples just described could also be performed using a homogeneous atmospheric glow discharge plasma.

Needless to say, the invention is not limited to the examples just described, and numerous adjustments may be made to these examples without departing from the context of the invention.

The invention, as just described, clearly achieves its stated aim and makes it possible to propose a transparent optical element having at least one or more properties such as anticorrosion properties, antifogging properties, antiabrasion properties, antiselection properties, barrier properties to compensate for the effects of outgassing from the first layer, for example, self-repairing and/or self-cleaning properties by virtue of super-hydrophobicity and/or induced photocatalysis, meltable or unmeltable properties, these properties being obtained by means of at least one second layer deposited on a first layer, the second layer comprising at least one polymer formed by polymerization of a monomer, the polymerization being assisted with an atmospheric silent-discharge plasma.

Variants not described herein may be performed without departing from the context of the invention, provided that, in accordance with the invention, they comprise at least one second layer deposited on a transparent first layer and formed by polymerization of at least one precursor compound, the polymerization being due to a volume dielectric barrier atmospheric discharge plasma.

1. A transparent optical element (51) for a vehicle, comprising at least a first transparent layer (53) made of a polymer material, characterized in that the transparent optical element (51) comprises at least a second transparent layer (55, 551, 552, 553, 554) formed by the polymerization of at least one precursor compound (PC1, PC2, PC3, PC4, PC5), the polymerization being assisted by means of a volume dielectric barrier atmospheric discharge plasma.

2. The optical element (51) as claimed in the preceding claim, in which the second layer has a thickness of not more than 1 micrometer.

3. The optical element (51) as claimed in either of the preceding claims, in which the precursor compound (PC, PC1, PC2, PC3, PC4, PC5) is chosen from an organic monomer, an organometallic monomer, an organic prepolymer and mixtures thereof.

4. The optical element (51) as claimed in any one of the preceding claims, in which the polymerization of the precursor compound (PC1) is performed in the presence of a second precursor compound (PC2).

5. The optical element (51) as claimed in the preceding claim, in which the second precursor (PC2) is a crosslinking agent.

6. The optical element (51) as claimed in any one of the preceding claims, comprising a plurality of transparent second layers (55, 551, 552, 553, 554, 555), each second layer being formed by polymerization of at least one precursor compound (PC1, PC2, PC3, PC4, PC5), the polymerization being assisted by means of a volume dielectric barrier atmospheric discharge plasma.

7. The optical element (51) as claimed in any one of the claims, in which the plasma is created and maintained by an ionizable gas (IG) introduced between two electrodes (5, 7) separated by a dielectric (6), the electrodes (5, 7) being fed with electric current by an electric generator configured to provide an electric power of between 50 and 500 W.

8. The optical element (51) as claimed in the preceding claim, in which the ionizable gas (IG) is unpolymerizable and neutral, the volumetric flow rate of the ionizable gas (IG) being between 60 ls/min and 100 ls/min.

9. The optical element (51) as claimed in any one of the preceding claims, in which a dilution gas (DG, DG2) is used to adjust the concentration of the precursor compound (PC1, PC2, PC3, PC4, PC5) in the volume dielectric barrier atmospheric discharge plasma, the volumetric flow rate of the dilution gas being between 2 ls/min and 8 ls/min.

10. The transparent optical element (51) as claimed in any one of the preceding claims, in which the polymer material of the first transparent layer comprises at least one polymer chosen from polycarbonate (PC), high-temperature modified polycarbonate (PC-HT), polymethyl methacrylate (PMMA), polymethacryl methyl imide (PMMI), cycloolefin polymer (COP), cycloolefin copolymer (COC), polysulfone (PSU), polyarylate (PAR), polyamide (PA), and mixtures thereof.
